(19) United States
(12) Patent Application Publication
(10) Pub. No.: US 2025/0125198 A1
(43) Pub. Date: Apr. 17, 2025

(54) PROCESSING METHOD

(71) Applicant: DISCO CORPORATION, Tokyo (JP)

(72) Inventors: Masayuki KAWASE, Tokyo (JP); Ye CHEN, Tokyo (JP)

(21) Appl. No.: 18/904,340

(22) Filed: Oct. 2, 2024

(30) Foreign Application Priority Data
Oct. 16, 2023 (JP) 2023-178168

(51) Int. Cl. H01L 21/78

(52) U.S. Cl. CPC H01L 21/78

(57) ABSTRACT

A processing method is of cutting a substrate using a processing device. The processing device includes a holding table for holding the substrate, a processing unit having a processing tool to process the substrate, a Y-direction moving unit configured to relatively move the holding table and the processing unit in a Y-direction, and an X-direction moving unit configured to relatively move the holding table and the processing unit in an X-direction. The processing method includes: holding the substrate with the holding table; positioning an outer edge of the processing tool inward, by a predetermined amount, of one end side of the substrate in the X-direction; processing the substrate; positioning an outer edge of the processing tool inward, by a predetermined amount, of the other end side in the X-direction of the substrate; and then processing the substrate.

### CROSS-REFERENCE TO RELATED APPLICATION(S)

The present application claims priority to and incorporates by reference the entire contents of Japanese Patent Application No. 2023-178168 filed in Japan on Oct. 16, 2023.

### BACKGROUND

The present disclosure relates to a processing method.

In recent years, substrates on which devices are built have been increased in size in order to improve production efficiency. For example, there is a large substrate in which a plurality of semiconductor chips having bumps on the surface are mounted and these semiconductor chips are sealed with resin. To perform turning cutting on a surface of such a large substrate, there has been proposed a single-point cutting device capable of moving a tool bit wheel in a Y-direction, which is a processing feed direction, and also in an X-direction orthogonal to the Y-direction (see, for example, JP 2016-40063 A).

Some substrates in a trial production stage have a step or a protrusion at the end portion, and some substrates cannot be sucked and held up at the end portion with a holding table due to an increased size, and the end portion is likely to flutter during cutting. When such a substrate is cut, damage may be caused when a tool bit cuts into the end of the substrate, or processing defects may occur due to dragging the resin from the end portion. Since it is necessary to confirm the cuttability in a device region of the substrate at the trial production stage, there has been a demand for a cutting method that is not affected by the end portion of the substrate.

### SUMMARY

A processing method according to one aspect of the present disclosure is of cutting a substrate using a processing device. The processing device includes at least a holding table for holding the substrate, a processing unit having a processing tool to process the substrate held on the holding table, a Y-direction moving unit configured to relatively move the holding table and the processing unit in a Y-direction that is a processing feed direction, and an X-direction moving unit configured to relatively move the holding table and the processing unit in an X-direction orthogonal to the Y-direction. The processing method includes: holding the substrate with the holding table; positioning an outer edge of the processing tool inward, by a predetermined amount, of one end side of the substrate in the X-direction after holding the substrate; processing the substrate after positioning the outer edge of the processing tool inward of one end side of the substrate; positioning an outer edge of the processing tool inward, by a predetermined amount, of the other end side in the X-direction of the substrate after processing the substrate; and processing the substrate after positioning the outer edge of the processing tool inward of the other end side.

### BRIEF DESCRIPTION OF THE DRAWINGS

FIG. 1 is a cross-sectional view of a main part of a substrate to be processed by a processing method according to a first embodiment;

FIG. 2 is a perspective view schematically illustrating a configuration example of a single-point cutting device that executes the processing method according to the first embodiment;

FIG. 3 is a flowchart illustrating a flow of the processing method according to the first embodiment;

FIG. 4 is a plan view schematically illustrating a first positioning step of the processing method illustrated in FIG. 3; and

FIG. 5 is a plan view schematically illustrating a second positioning step of the processing method illustrated in FIG. 3.

### DETAILED DESCRIPTION

A mode (embodiment) for carrying out the present disclosure will be described in detail with reference to the drawings. The present invention is not limited to the following embodiments. Further, the components described below encompass those which those skilled in the art could easily have arrived at and those that are substantially the same. Moreover, configurations described below can be appropriately combined. Various omissions, substitutions, alterations, modifications or changes in the configuration can be made without departing from the gist of the present invention.

### First Embodiment

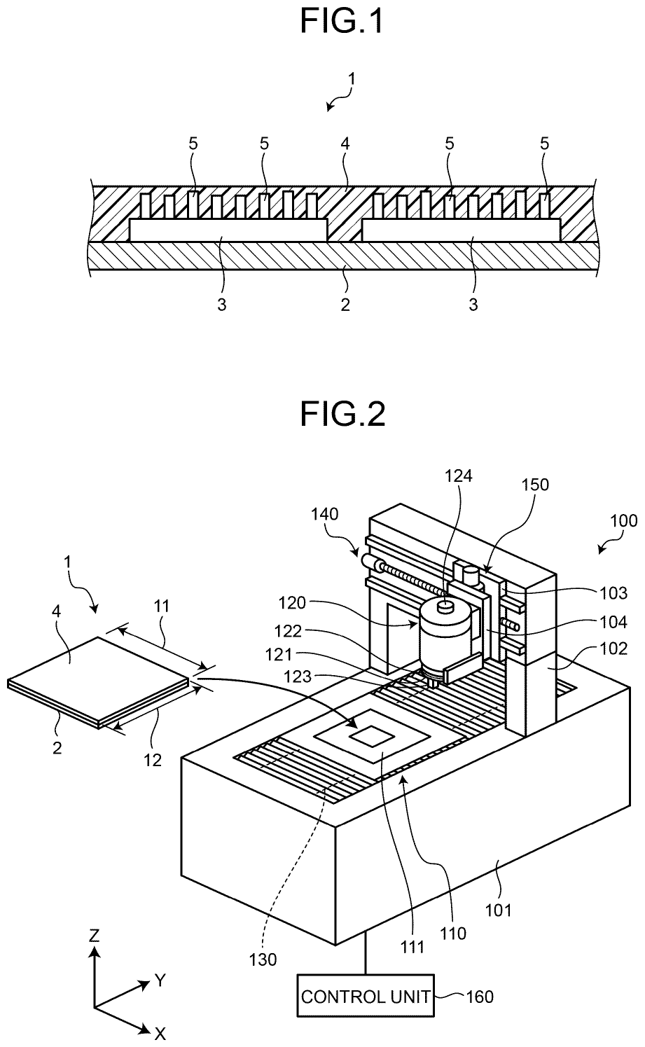

A processing method according to a first embodiment of the present disclosure will be described with reference to the drawings. FIG. 1 is a cross-sectional view of a main part of a substrate to be processed by the processing method according to the first embodiment. FIG. 2 is a perspective view schematically illustrating a configuration example of a single-point cutting device that executes the processing method according to the first embodiment.

### Substrate

The processing method according to the first embodiment is a method of single-point cutting (corresponding to processing) sealing resin 4 of a substrate 1 illustrated in FIG. 1. As illustrated in FIG. 1, the substrate 1 to be processed by the processing method according to the first embodiment includes a base substrate 2 having a rectangular shape, a plurality of chips 3 mounted on the base substrate 2, and sealing resin 4 sealing the chips 3, and has a planar shape formed in a rectangular shape. In the first embodiment, a width 11 (illustrated in FIG. 2) of the substrate 1 is, for example, 515 mm, and a length 12 of the substrate 1 is, for example, 510 mm.

Further, the substrate 1 is formed to have a constant thickness. In the first embodiment, the chips 3 are arranged at equal intervals in two directions orthogonal to each other on a surface of the substrate 1. In the first embodiment, each of the chips 3 has a plurality of bumps 5 (projecting electrodes). The sealing resin 4 is laminated on the surface of the base substrate 2 to seal the chips 3. In the embodiment, the sealing resin 4 is laminated over the entire surface of the base substrate 2.

After at least a part of the surface of the sealing resin 4 is cut by single-point cutting and flattened by means of the processing method, the substrate 1 is divided for each of the chips 3 by, for example, cutting between the chips 3.

### Single-Point Cutting Device

The processing method according to the first embodiment is performed by a single-point cutting device 100 (corresponding to a processing device) illustrated in FIG. 2. The single-point cutting device 100 illustrated in FIG. 2 is a processing device that performs single-point cutting (also known as turning cutting) on at least a part of the surface of the sealing resin 4 on the substrate 1 with a tool bit to flatten at least a part of the surface of the sealing resin 4 on the substrate 1. As illustrated in FIG. 2, the single-point cutting device 100 includes at least a device base 101, a holding table 110, a single-point cutting unit 120, a processing feed unit 130, a processing position changing unit 140, a cutting feed unit 150, and a control unit 160.

The holding table 110 holds the base substrate 2 of the substrate 1 on a holding surface 111. In the first embodiment, in the holding table 110, the holding surface 111 which is an upper surface is formed flat along the horizontal direction, the holding surface 111 is formed in a rectangular shape, and the base substrate 2 of the substrate 1 is placed on the holding surface 111. In the first embodiment, a size of the holding surface 111 of the holding table 110 is equal to a size of the substrate 1.

In the holding table 110, the holding surface 111 is connected to a vacuum suction source (not illustrated). The holding table 110 sucks and holds the substrate 1 placed on the holding surface 111 by sucking the holding surface 111 by the suction source. The holding table 110 is provided movably in a Y-direction parallel to the horizontal direction by the processing feed unit 130. In the first embodiment, the Y-direction is parallel to the longitudinal direction of the device base 101.

The single-point cutting unit 120 is a processing unit that performs single-point cutting for the substrate 1 held on the holding table 110 with a tool bit wheel 121 attached to a lower end of a spindle (not illustrated). The single-point cutting unit 120 is supported by a gate-shaped support frame 102 standing upright from the device base 101 via the cutting feed unit 150 and the processing position changing unit 140.

The single-point cutting unit 120 includes a spindle (not illustrated), a motor 124 that rotates the spindle about an axis, and a tool bit wheel 121 attached to the lower end of the spindle. A central axis of the spindle is parallel to a Z-direction parallel to the vertical direction. The tool bit wheel 121 is attached to the lower end of the spindle. The spindle is rotated about the axis by the motor 124 to rotate the tool bit wheel 121 about the axis parallel to the Z-direction.

The tool bit wheel 121 performs single-point cutting for at least a part of the surface of the sealing resin 4 on the substrate 1 held on the holding table 110. The tool bit wheel 121 includes a wheel base 122 formed in an annular shape and attached to the lower end of the spindle, and a tool bit 123 (corresponding to a processing tool) provided on a lower surface of the wheel base 122, facing the holding surface 111. The tool bit 123 is formed in a columnar shape and is provided at an outer edge portion of the lower surface of the wheel base 122, and cuts into the surface of the sealing resin 4 on the substrate 1 by rotating the tool bit wheel 121 about the axis center to perform single-point cutting for at least a part of the surface of the sealing resin 4.

In the first embodiment, a diameter of the wheel base 122 of the tool bit wheel 121 is smaller than the width 11 of the substrate 1.

The processing feed unit 130 is a Y-direction moving unit that is installed on the device base 101 and relatively moves the holding table 110 and the single-point cutting unit 120 in the Y-direction which is a processing feed direction parallel to the holding surface 111. The processing feed unit 130 moves the holding table 110 in the Y-direction to move the holding table 110, apart from the single-point cutting unit 120, between a loading/unloading position at which the substrate 1 is loaded into and unloaded from the holding table 110 and a processing position located below the single-point cutting unit 120 and at which single-point cutting is performed by the single-point cutting unit 120. The processing feed unit 130 is a moving unit that moves the holding table 110 to the loading/unloading position and the processing position.

The processing position changing unit 140 is an X-direction moving unit that is installed on the support frame 102 and relatively moves the holding table 110 and the single-point cutting unit 120 in the X-direction parallel to the horizontal direction and orthogonal to the Y-direction. The processing position changing unit 140 moves the single-point cutting unit 120 in the X-direction by moving a moving frame 103 in the X-direction.

The cutting feed unit 150 is installed on the moving frame 103 and moves the single-point cutting unit 120 in the Z-direction which is a cutting feed direction orthogonal to the holding surface 111. The cutting feed unit 150 moves the single-point cutting unit 120 in the Z-direction by moving a second moving frame 104 supporting the single-point cutting unit 120 in the Z-direction.

The cutting feed unit 150 lowers the single-point cutting unit 120 to bring the tool bit 123 of the tool bit wheel 121 closer to the substrate 1 held on the holding table 110 at the processing position, and raises the single-point cutting unit 120 to move the tool bit 123 of the tool bit wheel 121 away from the substrate 1 held on the holding table 110 at the processing position.

The processing feed unit 130, the processing position changing unit 140, and the cutting feed unit 150 include a known ball screw rotatably provided around the axis, a known pulse motor and holding table 110 that rotate the ball screw around the axis, and a known guide rail that movably supports the moving frames 103 and 104 in the Y-direction, the X-direction, and the Z-direction.

The control unit 160 controls each of the above-described components constituting the single-point cutting device 100. That is, the control unit 160 causes the single-point cutting device 100 to execute the processing operation on the substrate 1. The control unit 160 is a computer that includes an arithmetic processing unit having a microprocessor such as a central processing unit (CPU), a storage device having a memory such as a read only memory (ROM) or a random access memory (RAM), and an input/output interface device, which is capable of executing a computer program.

The arithmetic processing unit of the control unit 160 executes a computer program stored in the ROM on the RAM to generate a control signal for controlling the single-point cutting device 100. The arithmetic processing unit of the control unit 160 outputs the generated control signal to each component of the single-point cutting device 100 via the input/output interface device.

Further, the control unit 160 is connected to a display unit (not illustrated) including, for example, a liquid crystal display device that displays a state of the processing operation or an image, and an input unit (not illustrated) used when an operator registers processing conditions. In the first embodiment, the input unit includes a touchscreen provided on the display unit.

### Processing Method

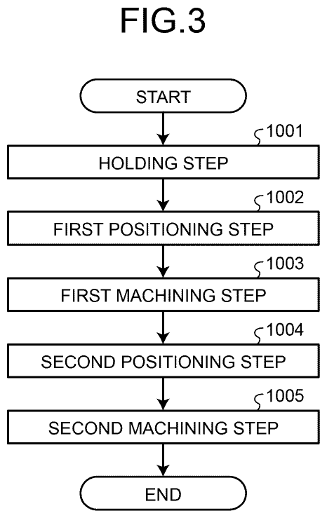

The processing method according to the first embodiment is a method of performing single-point cutting for at least a part of the sealing resin 4 on the substrate 1 using the single-point cutting device 100 described above. The processing method according to the first embodiment is also the processing operation of the single-point cutting device 100 described above. FIG. 3 is a flowchart illustrating a flow of the processing method according to the first embodiment.

As illustrated in FIG. 3, the processing method according to the first embodiment includes a holding step 1001, a first positioning step 1002, a first processing step 1003, a second positioning step 1004, and a second processing step 1005.

### Holding Step

The holding step 1001 is a step of holding the substrate 1 on the holding table 110. In the single-point cutting device 100 having the configuration described above, when the base substrate 2 of the substrate 1 before single-point cutting is placed on the holding surface 111 of the holding table 110 positioned at the loading/unloading position by the operator, the control unit 160 receives a processing condition input by the operator, and the control unit 160 receives an instruction to initiate the processing operation input by the operator, the processing operation, that is, the holding step 1001 of the processing method according to the first embodiment, is initiated.

In the first embodiment, the single-point cutting device 100 drives the motor 124 to start rotation of the spindle and the tool bit wheel 121 about the axis in the holding step 1001. In the first embodiment, the single-point cutting device 100 sucks and holds a side of the base substrate 2 on the substrate 1 on the holding surface 111 of the holding table 110 by the vacuum suction source in the holding step 1001. In the first embodiment, the substrate 1 is sucked and held on the holding table 110 with the width 11 of the substrate 1 parallel to the X-direction and the length 12 of the substrate 1 parallel to the Y-direction in the holding step 1001.

### First Positioning Step

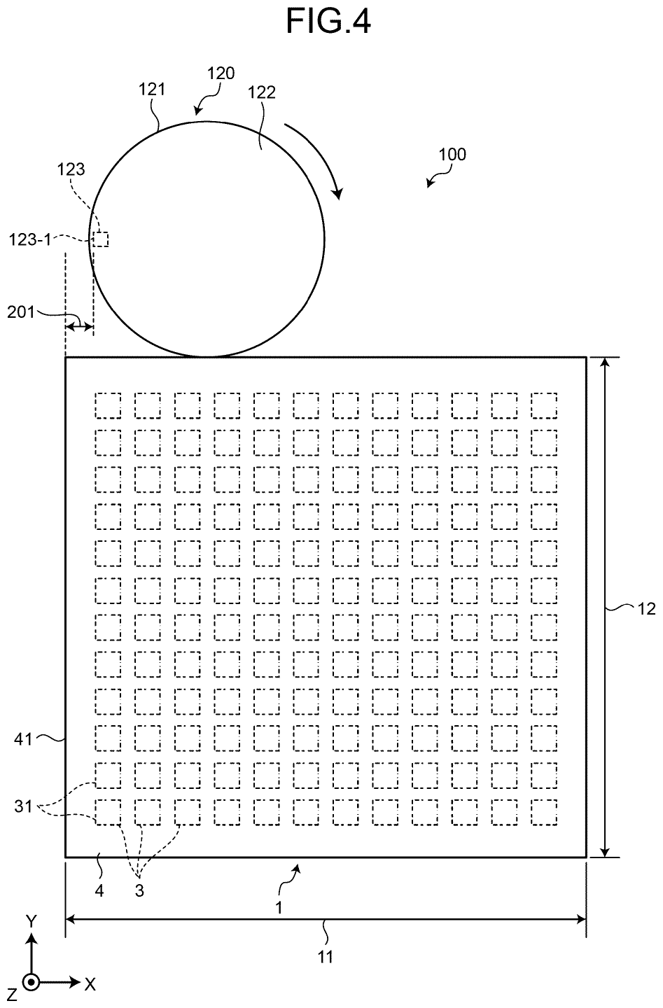

FIG. 4 is a plan view schematically illustrating the first positioning step of the processing method illustrated in FIG. 3. The first positioning step 1002 is a step of positioning an outer edge 123-1 of the tool bit 123 of the tool bit wheel 121 inward, by a predetermined amount 201, of one end side in the X-direction of the substrate 1 after the holding step 1001.

In the first embodiment, the single-point cutting device 100 causes the control unit 160 to control the processing position changing unit 140 to position the single-point cutting unit 120 at a position, as illustrated in FIG. 4, at which a distance from an outer edge 41 on one end side, in the X-direction, of the sealing resin 4 on the substrate 1 held on the holding table 110 to the outer edge 123-1 of the tool bit 123 when positioned closest to one end side of the substrate 1 in the X-direction is the predetermined amount 201 in the first positioning step 1002. Note that the predetermined amount 201 is a distance exceeding 0 and less than a distance by which the outer edge 123-1 of the tool bit 123 when positioned closest to one end side of the substrate 1 in the X-direction overlaps the outer edge 31 of the chip 3 closest to one end side of the substrate 1 in-the X direction, held on the holding table 110, in the Z-direction.

### First Processing Step

The first processing step 1003 is a step of performing single-point cutting for the substrate 1 after the first positioning step 1002. In the first embodiment, the single-point cutting device 100 causes the control unit 160 to control the cutting feed unit 150 to position the lower end of the tool bit 123 of the tool bit wheel 121 at a position where a height from the holding surface 111 is a desired height in the first processing step 1003. The desired height is desirably a height at which the tool bit 123 performs single-point cutting for the sealing resin 4 of the substrate 1.

In the first embodiment, the single-point cutting device 100 causes the control unit 160 to control the processing feed unit 130 to move the holding table 110 sucking and holding the substrate 1 in the Y-direction toward the processing position in the first processing step 1003. In the first embodiment, the single-point cutting device 100 performs single-point cutting by cutting the tool bit 123 into the sealing resin 4 on the substrate 1 held on the holding table 110 at the processing position while the control unit 160 supplies the cutting fluid to the tool bit wheel 121 in the first processing step 1003.

In the first embodiment, when the substrate 1 held on the holding table 110 passes below the tool bit wheel 121, the single-point cutting device 100 causes the control unit 160 to control the cutting feed unit 150 to raise the single-point cutting unit 120, and controls the processing feed unit 130 to move the holding table 110 to the loading/unloading position in the first processing step 1003.

### Second Positioning Step

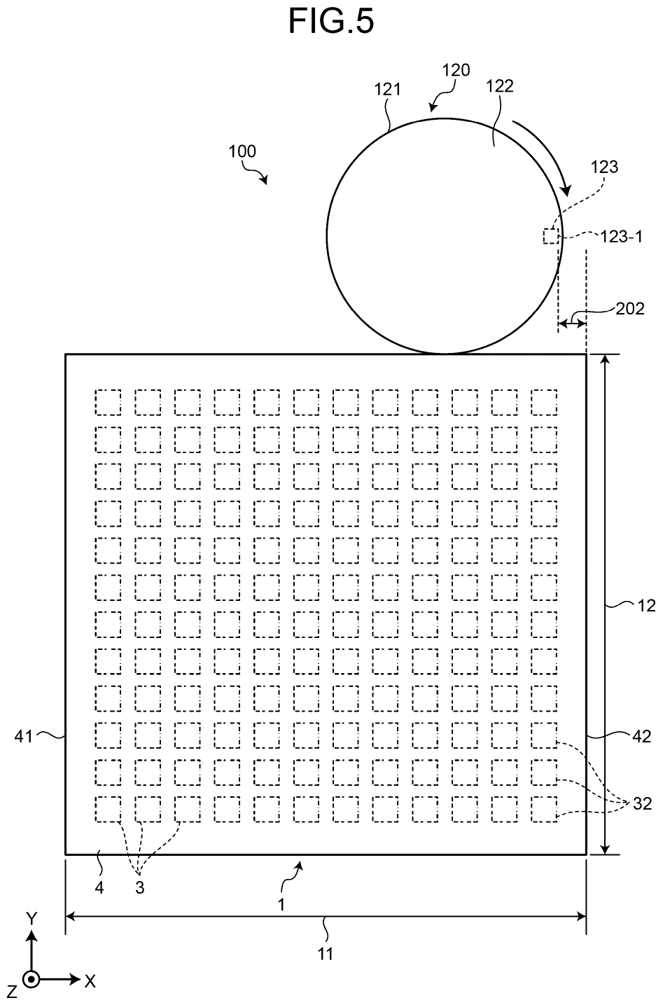

FIG. 5 is a plan view schematically illustrating the second positioning step of the processing method illustrated in FIG. 3. The second positioning step 1004 is a step of positioning the outer edge 123-1 of the tool bit 123 of the tool bit wheel 121 inward, by a predetermined amount 202, of the other end side in the X-direction of the substrate 1 after the first processing step 1003.

In the first embodiment, the single-point cutting device 100 causes the control unit 160 to control the processing position changing unit 140 to position the single-point cutting unit 120 at a position, as illustrated in FIG. 5, at which a distance from an outer edge 42 on the other end side, in the X-direction, of the sealing resin 4 on the substrate 1 held on the holding table 110 to the outer edge 123-1 of the tool bit 123 when positioned closest to the other end side of the substrate 1 in the X-direction is the predetermined amount 202 in the second positioning step 1004. Note that the predetermined amount 202 is a distance exceeding 0 and less than a distance by which the outer edge 123-1 of the tool bit 123 when positioned closest to the other end side of the substrate 1 in the X-direction overlaps the outer edge 32 of the chip 3 closest to the other end side of the substrate 1 in-the X direction, held on the holding table 110, in the Z-direction. In the first embodiment, the predetermined amount 202 may be equal to or different from the predetermined amount 201 in the first positioning step 1002.

### Second Processing Step

The second processing step 1005 is a step of performing single-point cutting for the substrate 1 after the second positioning step 1004. In the first embodiment, the single-point cutting device 100 causes the control unit 160 to control the cutting feed unit 150 to position the lower end of the tool bit 123 of the tool bit wheel 121 at a position where a height from the holding surface 111 is a desired height in the first processing step 1003.

In the first embodiment, the single-point cutting device 100 causes the control unit 160 to control the processing feed unit 130 to move the holding table 110 sucking and holding the substrate 1 in the Y-direction toward the processing position in the second processing step 1005. In the first embodiment, the single-point cutting device 100 performs single-point cutting by cutting the tool bit 123 into the sealing resin 4 on the substrate 1 held on the holding table 110 at the processing position while the control unit 160 supplies the cutting fluid to the tool bit wheel 121 in the second processing step 1005.

In the first embodiment, when the substrate 1 held on the holding table 110 passes below the tool bit wheel 121, the single-point cutting device 100 causes the control unit 160 to control the cutting feed unit 150 to raise the single-point cutting unit 120, and controls the processing feed unit 130 to move the holding table 110 to the loading/unloading position in the second processing step 1005. In the first embodiment, the single-point cutting device 100 stops suction and holding of the substrate 1 of the holding table 110, and ends the processing method in the second processing step 1005.

As described above, in the processing method according to the first embodiment, in the positioning steps 1002 and 1004, the single-point cutting unit 120 is positioned at a position where the distance from the outer edges 41 and 42 on both end sides, in the X-direction, of the sealing resin 4 on the substrate 1 held on the holding table 110 to the outer edge 123-1 of the tool bit 123 becomes the predetermined amount 201 or 202. Therefore, in the processing steps 1003 and 1005, an uncut region not subjected to single-point cutting remains at both ends in the X-direction of the sealing resin 4, and the sealing resin 4 is subjected to single-point cutting.

Therefore, in the processing method according to the first embodiment, even if there is a step or a protrusion on the outer edge of the sealing resin 4 of the substrate 1, single-point cutting can be suppressed, and even if the outer edge of the substrate 1 is not sucked and held by the holding surface 111, the outer edge of the sealing resin 4 of the substrate 1 is not subjected to single-point cutting in the processing steps 1003 and 1005, so that the substrate 1 is not much fluttered on the holding surface 111.

Therefore, the processing method according to the first embodiment has an advantageous effect that processing defects due to the influence of the end portion of the substrate 1 can be suppressed.

In the present disclosure, a central processing step of cutting a central portion in the X-direction of the substrate 1 sucked and held on the holding table 110 may be performed at least once or more between the first processing step 1003 and the second processing step 1005.

In the present disclosure, as long as a difference between the diameter of the wheel base 122 of the tool bit wheel 121 and the width 11 of the substrate 1 is small and the tool bit 123 can be simultaneously positioned at the position where the predetermined amount 201 or 202 is obtained, the first positioning step 1002 and the second positioning step 1004 may be simultaneously performed, and the first processing step 1003 and the second processing step 1005 may be simultaneously performed. That is, in the present disclosure, the first processing step 1003 and the second processing step 1005 may be simultaneously performed by the same single-point cutting.

In the present disclosure, the substrate 1 to be processed may not be laminated on the entire surface of the base substrate 2 as long as the sealing resin 4 seals the chips 3.

In the present disclosure, in the processing method, a grinding device (corresponding to a processing device) including a grinding unit as processing unit may perform so-called creep feed grinding (corresponding to processing) of the substrate 1. In this case, a grinding wheel of the grinding unit corresponds to the processing tool.

According to the present disclosure, it is possible to curb processing defects due to the influence of the end portion of the substrate.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A processing method of cutting a substrate using a processing device, the processing device including at least a holding table for holding the substrate, a processing unit having a processing tool to process the substrate held on the holding table, a Y-direction moving unit configured to relatively move the holding table and the processing unit in a Y-direction that is a processing feed direction, and an X-direction moving unit configured to relatively move the holding table and the processing unit in an X-direction orthogonal to the Y-direction, the processing method comprising:
holding the substrate with the holding table;
positioning an outer edge of the processing tool inward, by a predetermined amount, of one end side of the substrate in the X-direction after holding the substrate;
processing the substrate after positioning the outer edge of the processing tool inward of one end side of the substrate;
positioning an outer edge of the processing tool inward, by a predetermined amount, of the other end side in the X-direction of the substrate after processing the substrate; and
processing the substrate after positioning the outer edge of the processing tool inward of the other end side.
